(19) United States
(12) Patent Application Publication
(10) Pub. No.: US 2026/0114198 A1
(43) Pub. Date: Apr. 23, 2026

(54) METHODS OF FORMING SEMICONDUCTOR STRUCTURES

(71) Applicant: Semiconductor Manufacturing International (Shanghai) Corporation, Shanghai (CN)

(72) Inventor: Jisong JIN, Shanghai (CN)

(21) Appl. No.: 19/359,188

(22) Filed: Oct. 15, 2025

(30) Foreign Application Priority Data
Oct. 18, 2024 (CN) 202411466022.7

(51) Int. Cl. H01L 21/308; H01L 21/768

(52) U.S. Cl. CPC H10P 50/692; H10W 20/056

(57) ABSTRACT

A method for forming a semiconductor structure includes providing a base containing a first area and a second area; patterning a first core material layer and forming first core layers; forming first spacers; patterning a second core material layer and forming second core layers; forming second spacers covering sidewalls of the second core layers; forming a second protective layer; patterning the second core layers using the second protective layer as a mask and forming third core layers; and patterning a target material layer using the second spacers and the third core layers as a mask and forming first target structures and second target structures. A pitch between adjacent first target structures is smaller than or equal to a pitch between adjacent second target structures. The present invention achieves simultaneous arrangement of SAQP and SALELE processes and improves design flexibility in patterning.

### CROSS-REFERENCE TO RELATED APPLICATION

This application claims the priority of Chinese Patent Application No. 202411466022.7, filed on October 18, 2024, the content of which is incorporated herein by reference in its entirety.

### TECHNICAL FIELD

The present disclosure generally relates to the field of semiconductor manufacturing and, more particularly, relates to a method of forming a semiconductor structure.

### BACKGROUND

With the rapid advance of semiconductor manufacturing technologies, semiconductor devices are developing towards higher component density and higher integration. Photolithography technology is a commonly used patterning method and the most critical production technology in semiconductor manufacturing processes. Along with continuous reduction of pattern critical dimension (CD) and pitch, self-aligned double patterning (SADP) can no longer meet current process requirements, and self-aligned quadruple patterning (SAQP) method comes into being. Generally, the minimum pitch that SADP can form with the deep ultraviolet (DUV) technology is about half of the pitch limit of 76 nm for a single DUV exposure, which is a pitch of 38 nm. As such, the limit of SAQP with the DUV technology is a pitch of 19 nm. When a good yield is ensured, the general SADP limit is around 40 nm, and the SAQP limit is around 24 nm. In the back-end process, the SADP or SAQP process is often not used to form metal patterns, while self-aligned litho-etch litho-etch or spacer assisted litho-etch litho-etch (SALELE) is often used. SALELE has the advantage of more design freedom than SADP, but the metal pitch limit is similar to SADP, and the minimum pitch can only be about 40 nm.

However, as the size of transistors and chips shrinks, the back-end metal pitch also needs to reach a value of smaller than 40 nm to 30 nm or even a smaller pitch. The traditional SAQP method can achieve smaller pitches, but like SADP, it has major limitations in metal line layout design. Metal line layout generally needs to take into account both smaller pitches and large pitches on the same chip, as well as design freedom such as freely placed metal line positions, which is difficult to achieve using purely the SAQP process. However, in the absence of extreme ultraviolet (EUV) exposure processing, it is relatively difficult to achieve both pitch reduction and design freedom through the SAQP process that only uses the DUV lithography. It also has great limitations on production of chips with more advanced processes.

The disclosed structures and methods are directed to at least partially alleviating one or more problems set forth above and to solving other problems in the art.

### SUMMARY

One aspect of the present disclosure provides a method for forming a semiconductor structure. The method includes providing a base, wherein the base includes a substrate and a target material layer on the substrate, a second core material layer and a first core material layer over the second core material layer are formed over the base, the base further includes a first area for forming first target structures and a second area for forming second target structures, the first target structures and the second target structures extend along a first direction, and a pitch between adjacent first target structures is smaller than or equal to a pitch between adjacent second target structures; patterning the first core material layer and forming first core layers that are separate in the first area, extend along the first direction, and are arranged parallel to each other along a second direction, wherein the first direction is perpendicular to the second direction; forming first spacers covering sidewalls of the first core layers; removing the first core layers; forming a first protective layer over the second core material layer in the second area, wherein the first protective layer has first protective layer openings that are separate, extend along the first direction, and are arranged parallel to each other along the second direction; using the first protective layer and the first spacers as a mask to pattern the second core material layer, and forming second core layers and second core layer openings in the second core layers corresponding to the first protective layer openings, wherein the second core layer openings are surrounded by the second core layers in the second area; removing the first protective layer and the first spacers; forming second spacers covering sidewalls of the second core layers; forming a second protective layer on the second core layers in the second area, wherein the second protective layer has second protective layer openings that are separate, extend along the first direction, and are arranged parallel to each other along the second direction, the second protective layer fills the second core layer openings, and the second protective layer openings expose the second core layers; using the second protective layer as a mask to pattern the second core layers, removing a part of the second core layers in the first area, removing a part of the second core layers exposed by the second protective layer openings in the second area, and retaining a remaining part of the second core layers in the second area as third core layers; removing the second protective layer; and using the second spacers and the third core layers as a mask to pattern the target material layer, and forming the first target structures in the first area and the second target structures in the second area.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1 to 31 illustrate schematic structural diagrams corresponding to steps in methods for forming a semiconductor structure according to various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

Embodiments of the present disclosure provide a method of forming a semiconductor structure. The method improves design freedom in patterning processes.

The method includes providing a base, wherein the base includes a substrate and a target material layer on the substrate, a second core material layer and a first core material layer over the second core material layer are formed on the base, the base further includes a first area for forming first target structures and a second area for forming second target structures, the first target structures and the second target structures extend along a first direction, and a pitch between adjacent first target structures is smaller than or equal to a pitch between adjacent second target structures; patterning the first core material layer and forming separate first core layers in the first area extending along the first direction and arranged parallel to each other along a second direction, wherein the first direction is perpendicular to the second direction; forming first spacers covering sidewalls of the first core layers; removing the first core layers; forming a first protective layer on the second core material layer in the second area, wherein the first protective layer has separate first protective layer openings extending along the first direction and arranged parallel to each other along the second direction; using the first protective layer and the first spacers as a mask to pattern the second core material layer, and forming second core layers and second core layer openings in the second core layers corresponding to the first protective layer openings, wherein the second core layer openings are surrounded by the second core layers in the second area; removing the first protective layer and the first spacers; forming second spacers covering sidewalls of the second core layers; forming a second protective layer on the second core layers in the second area, wherein the second protective layer has separate second protective layer openings extending along the first direction and arranged parallel to each other along the second direction, the second protective layer fills the second core layer openings, and the second protective layer openings expose the second core layers; using the second protective layer as a mask to pattern the second core layers, removing the second core layers in the first area, removing the second core layers exposed by the second protective layer openings in the second area, and retaining the remaining second core layers in the second area as third core layers; removing the second protective layer; and using the second spacers and the third core layers as a mask to pattern the target material layer, and forming first target structures in the first area and second target structures in the second area.

Compared with existing technologies, technical solutions of embodiments of the present disclosure have the following advantages:

In the formation method provided by embodiments of the present disclosure, the base includes a first area for forming first target structures and a second area for forming second target structures. A pitch between adjacent first target structures is smaller than or equal to a pitch between adjacent second target structures. The second spacers and third core layers are used as a mask to pattern the target material layer, and the first target structures are formed in the first area and the second target structures formed in the second area. In some embodiments, the first core layers are formed in the first area. First spacers are formed to cover sidewalls of the first core layers. A first protective layer is formed on the second core material layer in the second area. The first protective layer has separate first protective layer openings extending along the first direction and arranged parallel to each other along the second direction. The first spacers and the first protective layer are used as a mask to pattern the second core material layer and the second core layers are formed. In the first area, second spacers covering sidewalls of the second core layers are formed. The second spacers are used as a mask to pattern the target material layer, using an SAQP process. The SAQP process may form the first target structures with a smaller pitch. In the second area, the second protective layer is formed on the second core layers. The second protective layer is used as a mask to pattern the second core layers in the second area and third core layers are formed. The second spacers covering sidewalls of the second core layers and the third core layers are formed. The second spacers and the third core layers are used as a mask to pattern the target material layer. The second target structures with a larger pitch are formed through an SALELE process. As such, embodiments of the present disclosure may better integrate the SAQP process and SALELE process. Both the first target structures with a smaller pitch and the second target structures with a larger pitch may be formed over the same base. It is conducive to meeting more semiconductor process needs through process integration and improving design freedom in patterning processes.

As mentioned in the background section, the SALELE process is a common solution in back-end patterning. The process has two core values in patterning. The first value is the spacing between metal lines defined by two lithographies is determined by the thickness of the spacer during the process. The spacer is usually formed by an atomic layer deposition (ALD) process with very high uniformity. As such, the overlay of two lithographies does not cause a change of spacing between two adjacent metal lines. It also makes the spacing between metal lines very uniform and fixed, and opens a large process window for reliability tests such as time dependent dielectric breakdown (TDDB) and breakdown voltage (VBD). The second value is that the tip to tip of the metal lines defined by two lithographies may be formed very small by using cuts of patterning produced by other masks. Further, a cut corresponding to the first lithography and a cut corresponding to the second lithography may not interfere with each other. This is also called a self-aligned block process in the industry.

The above two advantages are the reason that SALELE not only balances the process difficulty at the back-end patterning, but also provides great design freedom. The SALELE process also has various similar solutions, such as that shown in CN111640668B and process solutions disclosed in US10991596B2.

In general, the minimum pitch created by immersion DUV (ArFi) in a single photolithography is about 80 nm. Thus, SALELE may use DUV equipment to achieve a minimum pitch of 38 nm to 40 nm, while more advanced chips require smaller pitches, such as 32 nm, 28 nm, 24 nm, etc.

With the traditional fin patterning, when a pitch reaches about 30 nm, the SAQP process may be used. Because SADP may only make a fin pattern with a minimum pitch of 38 nm, SADP needs to be repeated to become SAQP. The SAQP process may well meet the needs of fin patterning. Because fin patterns are relatively regular, the fin pitches in an area of a chip are generally fixed and regular, and the difference between areas is not very large. However, the SAQP solution has great limitations in the back-end process where metal lines have a high degree of freedom. For example, when metal patterns of SRAM are formed, metal lines formed by patterning are difficult to match patterns of the first metal layer of the traditional SRAM. Further, the width of metal lines formed by SAQP is relatively fixed, which also makes designs of other bypass circuits more difficult.

As such, currently for back-end patterning in semiconductor structures of the same area, it is difficult to achieve both smaller pitch and design freedom, meet more requirements of semiconductor processes, and improve design freedom in patterning processes correspondingly.

In order to solve the above technical problems, embodiments of the present disclosure provide a method for forming a semiconductor structure. The method includes providing a base including a substrate and a target material layer on the substrate, forming a second core material layer over the substrate, and forming a first core material layer over the second core material layer, wherein the base includes a first area for forming first target structures and a second area for forming second target structures, the first target structures and the second target structures each extend along a first direction, and a pitch between adjacent first target structures is smaller than or equal to a pitch between adjacent second target structures; patterning the first core material layer and forming separate first core layers in the first area extending along the first direction and arranged parallel to each other along a second direction, wherein the first direction is perpendicular to the second direction; forming first spacers covering sidewalls of the first core layers; removing the first core layers; forming a first protective layer on the second core material layer in the second area, wherein the first protective layer has separate first protective layer openings extending along the first direction and arranged parallel to each other along the second direction; using the first protective layer and the first spacers as a mask to pattern the second core material layer, and forming second core layers and second core layer openings in the second core layers corresponding to the first protective layer openings, wherein the second core layer openings are surrounded by the second core layers in the second area; removing the first protective layer and the first spacers; forming second spacers covering sidewalls of the second core layers; forming a second protective layer on the second core layers in the second area, wherein the second protective layer has separate second protective layer openings extending along the first direction and arranged parallel to each other along the second direction, the second protective layer fills the second core layer openings, and the second protective layer openings expose the second core layers; using the second protective layer as a mask to pattern the second core layers, removing the second core layers in the first area, removing the second core layers exposed by the second protective layer openings in the second area, and retaining remaining second core layers in the second area as third core layers; removing the second protective layer; and using the second spacers and the third core layers as a mask to pattern the target material layer, and forming the first target structures in the first area and the second target structures in the second area.

In some embodiments, the first core layers are formed in the first area. The first spacers are formed to cover sidewalls of the first core layers. The first protective layer is formed on the second core material layer in the second area. Separate first protective layer openings are formed in the first protective layer that extend along the first direction and are arranged parallel to each other along the second direction. The first spacers and the first protective layer are used as a mask to pattern a second core material layer and second core layers are formed. In the first area, second spacers covering sidewalls of the second core layers are formed. The second spacers are used as a mask to pattern a target material layer through the SAQP process. The SAQP process may form first target structures with a smaller pitch. In the second area, a second protective layer is formed on the second core layers. The second protective layer is used as a mask to pattern the second core layers in the second area and the third core layers are formed. The second spacers are formed to cover sidewalls of the second core layers and the third core layers. The second spacers and the third core layers are used as a mask to pattern the target material layer using an SALELE process for making second target structures. The second target structures with a larger pitch may be made using the SALELE process. Thus, embodiments of the present disclosure may better integrate the SAQP process and the SALELE process. Both the first target structures with a smaller pitch and the second target structures with a larger pitch may be formed over the same base. It is conducive to meeting more semiconductor process needs and improving the design freedom in patterning processes through process integration.

In order to make the above objects, features, and advantages of the present disclosure more obvious and understandable, specific embodiments of the present disclosure will be described in detail below in conjunction with the accompanying drawings.

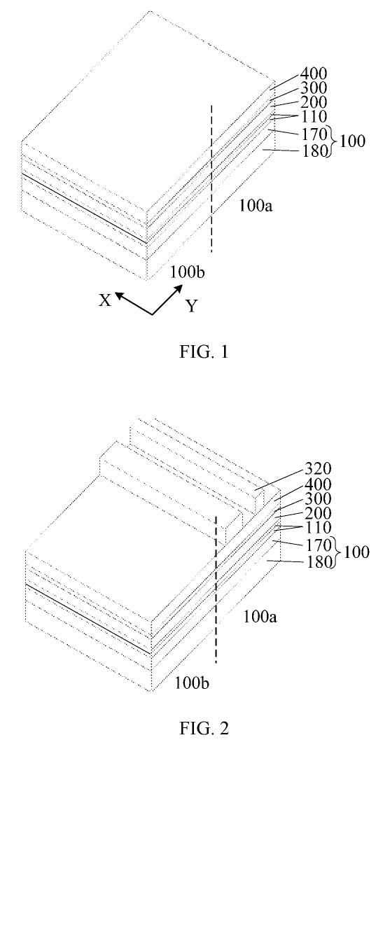

FIGS. 1 to 31 are schematic structural diagrams corresponding to steps of methods for forming a semiconductor structure according to embodiments of the present disclosure.

Referring to FIG. 1, a base 100 is provided. The base 100 includes a substrate 180 and a target material layer 170 on the substrate 180. A second core material layer 200 is formed over the base 100, and a first core material layer 400 is formed over the second core material layer 200. The base 100 includes a first area 100a for forming first target structures and a second area 100b for forming second target structures. Both the first target structure and second target structure extend along a first direction (i.e., the X direction in FIG. 1). The pitch of adjacent first target structures is smaller than or equal to the pitch of adjacent second target structures.

The base 100 provides a process operation basis for formation processes of semiconductor structures. Exemplarily, the semiconductor structures include metal interconnection lines, barrier layers, adhesion layers, cap layers, etc.

In some embodiments, the substrate 180 is a wafer on which transistors and part of connection lines are formed.

In some embodiments, the base 100 includes a first area 100a used for forming multiple first target structures and a second area 100b used for forming multiple second target structures. The pitch of adjacent first target structures is smaller than or equal to the pitch of adjacent second target structures.

In some embodiments, during formation processes of a semiconductor structure, it is necessary to form denser first target structures and sparser second target structures. For example, the pitch of adjacent first target structures is smaller than or equal to the pitch of adjacent second target structures. The SAQP process may be used to form denser target structures. However, it is hard to use SAQP to create sparser target structures. In addition, the pitch between target structures is relatively fixed and difficult to adjust freely according to layout needs. When the SALELE process is used, the pitch between target structures may be defined according to the layout. Further, the pitch is easy to adjust, and a self-aligned block process may be realized. However, it is difficult to use SALELE to form denser (e.g., a pitch smaller than 38 nm) target structures. In some embodiments, the SAQP process is used in the first area 100a, and the SALELE process is used in the second area 100b. As such, the base 100 including the first area 100a for forming the first target structures and the second area 100b for forming the second target structures indicates the following may be achieved in some embodiments: Fabricating the first target structures with smaller pitches that are difficult to make with SALELE and fabricating the second target structures with larger pitches that are difficult to make with SAQP and having more freedom in design over the same base 100 (e.g., a same wafer).

In some embodiments, the first area 100a includes a logic device area. The second area 100b includes a peripheral device area. The logic device area has denser patterns, and the peripheral device area has sparser patterns. Optionally, the logical device area includes device areas containing a central processing unit (CPU) and a graphics processing unit (GPU), and the peripheral device area includes device areas containing static random-access memory (SRAM), input and output (IO) devices, etc.

Optionally, the pitch of adjacent first target structures is 24 nm to 38 nm and the pitch of adjacent second target structures is 38 nm to 200 nm.

Thus, the SAQP process may be used to form the first target structures, and the SALELE process may be used to form the second target structures. The first target structures with a pitch of 24 nm to 38 nm and the second target structures with a pitch of 38 nm to 200 nm may be formed over the same base 100.

In some embodiments, the thickness of gate oxide layers in the logic device area is smaller than the thickness of gate oxide layers in the peripheral device area. Generally, the operating voltage of CPU or GPU transistors is lower than that of transistors in the IO device area. For example, the operating voltage of CPU transistors may be 0.75 V, while the operating voltage of transistors in an IO device area may be 1.2 V or even 1.8 V. Usually, in order to maintain the reliability and electrical performance of transistors in an IO device area, the gate oxide layer of transistors in the IO device area may be thicker than that in a logic device area. The thickness difference mainly comes from the thickness of a high-K (HK) dielectric layer of a high-K metal gate (HKMG) and the thickness of an interface layer (e.g., a silicon oxide layer) between transistor channels. Optionally, the interface layer in a gate oxide layer of the logic device area is thinner than that in the IO device area, and the HK dielectric layers over the interface layer in the two areas have the same thickness. The interface layer and HK dielectric layer together form a gate dielectric layer of a corresponding transistor. Thus, the thickness of a gate oxide layer in the logic device area is smaller than that in the peripheral device area.

The target material layer 170 is used to provide a process platform for forming the first target structures and the second target structures.

In some embodiments, in the step of providing the base 100, the target material layer 170 is a dielectric layer, the first target structures are first trenches, and the second target structures are second trenches.

The first trench and second trench provide spatial locations for subsequent processes. The target material layer 170 is a dielectric layer used to isolate structures formed in the first trench and second trench.

In some embodiments, materials of the dielectric layer include one or more of silicon oxide, silicon nitride, silicon oxynitride, silicon oxycarbide, silicon carbonitride, silicon oxynitride, a low-K (LK) material (e.g., a material of an LK dielectric layer), and an ultralow-K (ULK) material (e.g., a material of an ULK dielectric layer).

In some embodiments, in the step of providing the base 100, a mask material layer 110 is also formed between the target material layer 170 and the second core material layer 200.

The mask material layer 110 is used to subsequently form a second pattern transfer layer.

In some embodiments, the mask material layer 110 has a stacked structure, including a titanium nitride layer and a silicon oxide layer over the titanium nitride layer.

The second core material layer 200 is used to subsequently form second core layers and third core layers.

In some embodiments, after the second core layers are subsequently formed, part of the second core layers will be removed later. Thus, the material of the second core material layer 200 may be a material that is easy to remove, thereby reducing the difficulty of removing the second core layers and reducing the damage to other layers located below the second core material layer 200. Materials of the second core material layer 200 may include one or more of amorphous silicon (a-Si), polycrystalline silicon, single crystal silicon, silicon oxide, advanced patterning film (APF) material, spin on carbon (SOC), and silicon carbide. For example, the material of the second core material layer 200 may be a-Si in some cases.

In some embodiments, in the step of providing the base 100, an etching stop layer 300 may be also formed between the first core material layer 400 and the second core material layer 200.

The etching stop layer 300 is used to subsequently form a first pattern transfer layer. The etching stop layer 300 is also used as an etch stop layer when the first core material layer 400 is subsequently patterned, and to protect the second core material layer 200 and prevent the second core material layer 200 from being damaged.

In some embodiments, materials of the etching stop layer 300 include one or more of silicon oxide, silicon nitride, silicon oxynitride, silicon carbide, titanium, titanium oxide, titanium nitride, tantalum, tantalum oxide, tantalum nitride, boron nitride, copper nitride, aluminum nitride, and tungsten nitride. For example, the material of the etching stop layer 300 may be silicon oxide in some cases.

The first core material layer 400 is used to subsequently form the first core layers.

In some embodiments, after the first core layers are subsequently formed, the first core layers will be removed later. Thus, the material of the first core material layer 400 may be a material that is easy to remove, thereby reducing difficulties of removing the first core layers and reducing damage to other layers located below the first core material layer 400. Materials of the first core material layer 400 may include one or more of a-Si, polycrystalline silicon, single crystal silicon, silicon oxide, APF material, SOC, and silicon carbide. For example, the material of the first core material layer 400 may be a-Si in some cases.

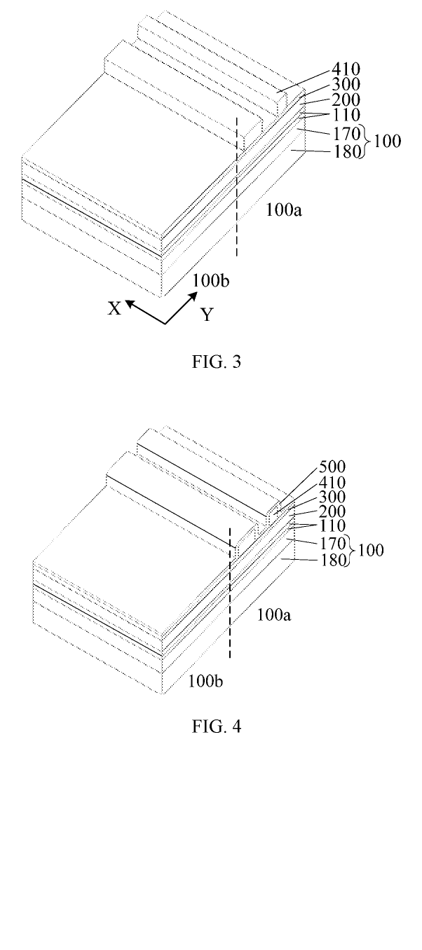

With reference to FIGS. 2 and 3, the first core material layer 400 is patterned, and separate first core layers 410 are formed in the first area 100a. The first core layers 410 extend along a first direction (i.e., the X direction in FIG. 3) and are arranged in parallel along a second direction (i.e., the Y direction in FIG. 3). The first direction is perpendicular to the second direction.

The first core layers 410 are used to provide support for the subsequent formation of first spacers.

In some embodiments, the first core material layer 400 is patterned using a dry etching process. The dry etching of a-Si is easier to stop at the silicon oxide material used as the first etching stop layer 300 in some embodiments.

The dry etch process is an etching process with anisotropic etching characteristics, and its longitudinal etching rate is much greater than the lateral etching rate. Therefore, by selecting a dry etching process, it is beneficial to improve the accuracy of pattern transfer. At the same time, dry etching is more directional and conducive to improving the sidewall topography quality and dimensional accuracy of the first core layers 410.

Correspondingly, in some embodiments, the material of the first core layers 410 is a-Si, so that during the process of patterning the first core material layer 400, damage to the etching stop layer 300 is reduced. After the first core material layer 400 is patterned, the etching stop layer 300 still maintains a good size and topography accuracy. Moreover, the first core layers 410 are made of a material that is easy to remove, and the subsequent removal process of the first core layers 410 has less impact on the etching stop layer 300.

Notably in some embodiments, the size and pitch of the first core layers 410 are set according to the size and pitch of the first target structures subsequently formed in the first area 100a.

Referring to FIG. 2, the step of patterning the first core material layer 400 includes forming separate first mask layers 320 over the first core material layer 400 in the first area 100a.

The first mask layers 320 are used as an etching mask for patterning the first core material layer 400.

In some embodiments, the first mask layer 320 includes an SOC layer, an anti-reflective coating (Si-ARC) on the SOC, and a photoresist layer on the Si-ARC. The first mask layer 320 may be formed through photolithography and several etching steps.

Referring to FIG. 3, the first core material layer 400 is patterned via the first mask layers 320. First core layers 410 are formed separately in the first area 100a.

In some embodiments, after the first core layers 410 are formed, the process also includes removing the first mask layers 320.

The first mask layers 320 are removed to prepare for subsequent formation of the first spacers.

Referring to FIGS. 4 and 5, first spacers 510 are formed that cover the sidewalls of the first core layers 410.

The first spacers 510 are used as a mask for subsequently patterning the second core material layer 200.

In some embodiments, materials of the first spacers 510 include one or more of titanium oxide, titanium nitride, silicon oxide, silicon nitride, silicon oxynitride, and silicon carbide.

Titanium oxide, titanium nitride, silicon oxide, silicon nitride, silicon oxynitride, and silicon carbide may form a better etching selectivity ratio with respect to the first core layers 410, thereby reducing the damage to the first spacers 510 in subsequent steps of removing the first core layers 410.

Referring to FIG. 4, the step of forming the first spacers 510 covering the sidewalls of the first core layers 410 includes forming a first spacer material layer 500 covering the sidewalls and tops of the first core layers 410 and the top of the second core material layer 200.

In some embodiments, the first spacer material layer 500 covers the sidewalls and tops of the first core layers 410 and the top of the etching stop layer 300.

The first spacer material layer 500 is used to form the first spacers 510 directly. Correspondingly, materials of the first spacer material layer 500 include one or more of titanium oxide, titanium nitride, silicon oxide, silicon nitride, silicon oxynitride, and silicon carbide.

In some embodiments, an ALD process is used to form the first spacer material layer 500 that covers the sidewalls and tops of the first core layers 410 and the top of the etching stop layer 300.

The first spacer material layer 500 formed by the ALD process has good thickness uniformity and good step coverage capability. As such, the first spacer material layer 500 may conformally cover the sidewalls and tops of the first core layers 410 and the top of the etching stop layer 300.

Referring to FIG. 5, the first spacer material layer 500 located on the tops of the first core layers 410 and the second core material layer 200 is removed. Portions of the first spacer material layer 500 located on the sidewalls of the first core layers 410 are retained as the first spacers 510.

In some embodiments, the first spacer material layer 500 on the tops of the first core layers 410 and the etch stop layer 300 is removed.

Optionally, the first spacer material layer 500 on the tops of the first core layers 410 and the etch stop layer 300 may be removed by dry etch.

Dry etch is an anisotropic etching process. As such, the dry etching process is beneficial to reduce the damage to the first core layers 410 and the etching stop layer 300. Further, dry etch is more directional on etching, which is beneficial to improve the sidewall topography quality and dimensional accuracy of the first spacers 510.

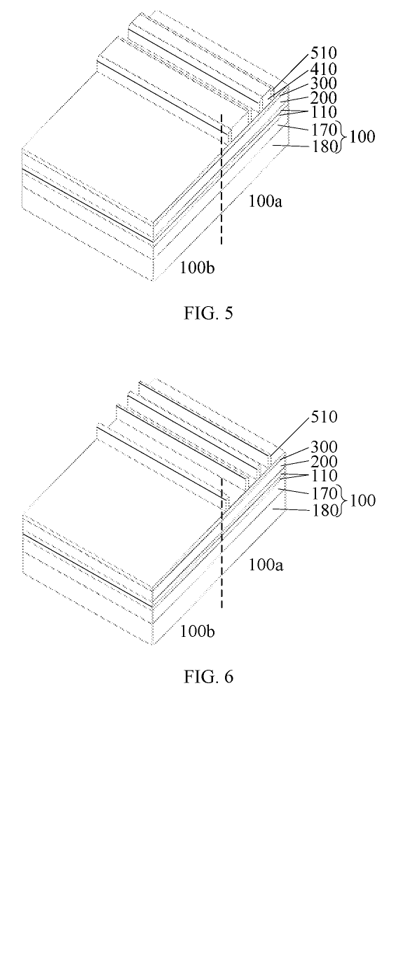

Referring to FIG. 6, the first core layers 410 are removed.

Removing the first core layer 410 is used to prepare for subsequent patterning of the etching stop layer 300 and the second core material layer 200 using the first spacers 510 as a mask.

In some embodiments, a wet etching process is used to remove the first core layers 410.

Wet etch has characteristics of isotropic etching, which is conducive to removing the first core layers 410 completely. Moreover, the cost of wet etch is relatively low, the operation steps are simple, and it may also achieve a large etch selectivity ratio. It is beneficial to reduce the damage to the first spacers 510 during the process of removing the first core layers 410.

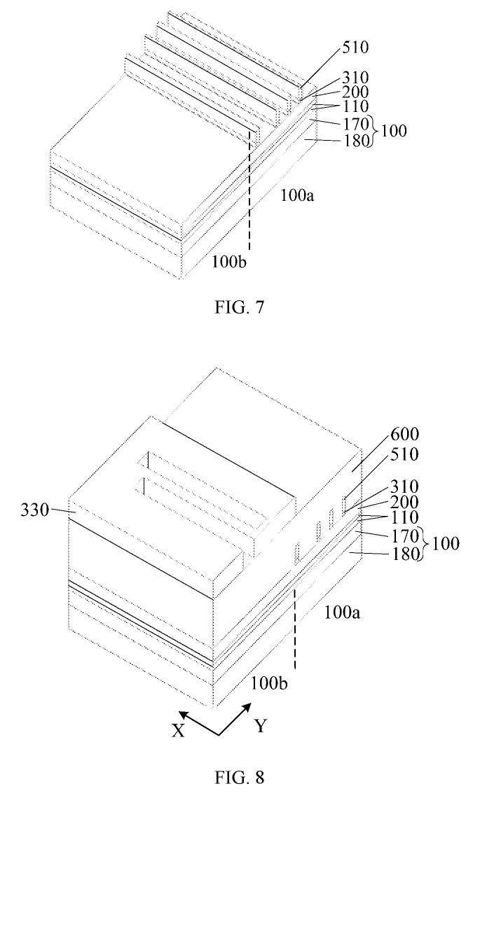

Referring to FIG. 7, before forming a first protective layer over the second core material layer 200 in the second area 100b, the first spacers 510 are used as a mask to pattern the etching stop layer 300 and first pattern transfer layers 310 are made.

The first pattern transfer layers 310 are used as an etching mask for subsequent patterning of the second core material layer 200 in the first area 100a.

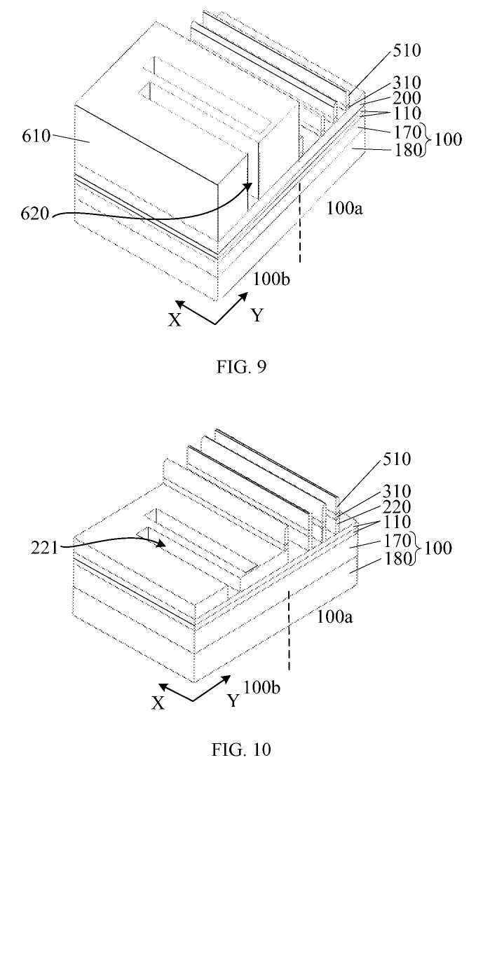

With reference to FIGS. 8 and 9, a first protective layer 610 is formed on the second core material layer 200 in the second area 100b. The first protective layer 610 has separate first protective layer openings 620 extending along the first direction and arranged parallel to each other along the second direction.

The first protective layer 610 serves as an etch mask for subsequent patterning of the second core material layer 200.

In some embodiments, the first protective layer 610 is formed by patterning a planarization layer, and the material of the first protective layer 610 includes SOC material or SOC with residual portions of the second mask layer 330. The presence or absence of residual second mask layer 330 depends on process selection and does not affect subsequent steps. SOC may be formed by a spin-coating process with low cost. By using SOC, it is beneficial to improve the flatness of the top surface, thereby providing a good interface for the formation of the first protective layers.

In some embodiments, in the step of forming the first protective layer 610 on the second core material layer 200 in the second area 100b, the first protective layer openings 620 have a dimension of 35 nm to 200 nm along the second direction and a pitch of 76 nm to 200 nm. The second core material layer 200 in the second area 100b is subsequently patterned, and the second core layer openings are formed with a dimension of 35 nm to 200 nm along the second direction and a pitch of 76 nm to 200 nm.

Referring to FIG. 8, the step of forming the first protective layer 610 on the second core material layer 200 in the second area 100b includes forming a first protective material layer 600 covering the second core material layer 200, the first spacers 510, and sidewalls of the first pattern transfer layers 310.

In some embodiments, a second mask layer 330 is formed on the first protective material layer 600. The second mask layer 330 exposes the first protective material layer 600 in the first area 100a and is located on the first protective material layer 600 in the second area 100b.

The second mask layer 330 is used to pattern the first protective material layer 600.

In some embodiments, the second mask layer includes Si-ARC and a photoresist layer located over the Si-ARC.

In some embodiments, a photomask and related lithography and etching processes are used to pattern the second mask layer 330 located in the first area 100a and the second area 100b. The second mask layer 330 is then used to pattern the first protective material layer 600, forming the first protective layer 610. Subsequently, the second core material layer 200 is patterned using the first protective layer 610 in the second area 100b and the first spacers 510 in the first area as a mask, thereby forming the second core layers. Since a single photomask is employed to define the second mask layer 330, the process offers high flexibility and diverse patterns, and the design is relatively free within the scope allowed by a single lithography. That is, the dimensions and pitch of the first protective layer openings 620 in the first protective layer 610 is relatively freely designed, as long as they comply with the constraints of single DUV lithography, such as a pitch greater than approximately 76 nm. This correspondingly enables relatively free design of the dimensions and pitch of the trenches surrounded by the second spacer material layer supported by the sidewalls of the second core layers. Consequently, the second target structures with larger pitches may be obtained in the second area 100b while improving design flexibility in patterning.

Referring to FIG. 9, the first protective material layer 600 is patterned. The first protective material layer 600 in the first area 100a is removed. Portions of the first protective material layer 600 in the second area 100b are removed. The removed portions in the second area 100b partially extend along the first direction and partially extend along the second direction, leaving remaining portions of the first protective material layer 600 in the second area 100b as the first protective layer 610.

Optionally, the first protective material layer 600 is patterned using the second mask layer 330 as an etch mask.

In some embodiments, after forming the first protective material layer 600 in the second area 100b as the first protective layer 610, the method further includes removing the second mask layer 330.

Referring to FIG. 10, the second core material layer 200 is patterned using the first spacers 510 and the first protective layer 610 as a mask. Second core layers 210 and second core layer openings 221 in the second core layers corresponding to the first protective layer openings are formed. The second core layer openings 221 are surrounded by the second core layers 220 in the second area 100b.

Optionally, the second core layers 220 formed in the first area 100a exhibit the morphology identical to the first spacers 510, extending along the first direction and arranged parallel to each other along the second direction. The second core layers 210 formed in the second area 100b have second core layer openings 221 that extend along the first direction and are arranged parallel to each other along the second direction, matching the first protective layer openings 620.

The second core layers 220 serve as a support for subsequent formation of the second spacers.

Correspondingly, in some embodiments, the material of the second core layers 220 is a-Si.

Correspondingly, in some embodiments, the second core layer openings 221 have a dimension of 35 nm to 200 nm along the second direction and a pitch of 76 nm to 200 nm.

In some embodiments, a dry etching process is employed to pattern the second core material layer 200 using the first protective layer 610 and the first spacers 510 as a mask.

The dry etching process is more directional, with a higher vertical etching rate than a lateral etching rate, which helps achieve better pattern transfer accuracy. This improves dimensional precision of the second core layers 220 and second core layer openings 221. It also enhances the sidewall quality of the second core layers 220.

In some embodiments, during the step of patterning the second core material layer 200 using the first spacers 510 and the first protective layer 610 as a mask, the second core material layer 200 in the first area 100a is patterned using the first pattern transfer layer 310 as a mask. Separate second core layers 220 are formed in the first area 100a.

The second core material layer 200 in the first area 100a is patterned using the first pattern transfer layer 310 as a mask and separate second core layers 220 are formed in the first area 100a, which helps improve pattern transfer accuracy, thereby enhancing dimensional precision of the second core layers 220.

The second core layers 220 in the first area 100a are transferred from the first spacers 510. The pitch of the first spacers 510 has already been halved from the pitch of the first mask layer 320. This represents an SADP process, achieving a reduction from the single DUV lithography limit of about 80 nm to about 40 nm. It prepares for the subsequent formation of the second spacers on the sidewalls of the second core layers, which will halve the pitch again compared to the first spacers 510. This is the characteristic of the SAQP process, which enables formation of patterns with pitches around 24 nm.

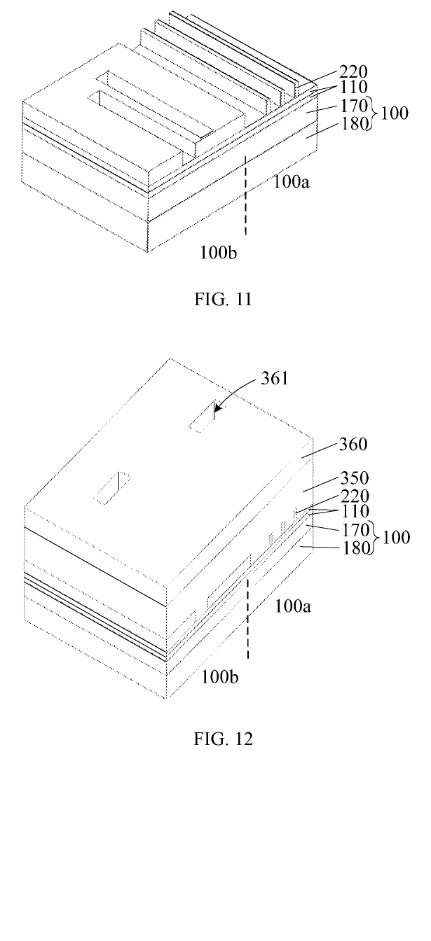

Referring to FIGS. 10 and 11, the first spacers 510 and the first protective layer 610 are removed. Removing the first spacers 510 and the first protective layer 610 prepares for subsequent formation of a second protective layer.

Referring to FIG. 10, an etching process is used to remove the first protective layer 610.

In some embodiments, either isotropic or anisotropic etching processes may be employed, provided that the etching selectivity ratio of the process is maintained to ensure a high selectivity between the first protective layer 610 and the second core layers 220. Thus, damage to the second core layers 220 is minimized during removal of the first protective layer 610.

Referring to FIG. 11, after forming the second core layers 220, the method further includes removing the first pattern transfer layer 310.

Removing the first pattern transfer layer 310 prepares for subsequent formation of the second spacers.

In some embodiments, a wet etching process is used to remove the first spacers 510 and the first pattern transfer layer 310.

The wet etching process, being isotropic, facilitates complete removal of the first spacers 510 and the first pattern transfer layer 310. Additionally, the wet etching process is relatively low-cost, involves simple steps, and may achieve a high etching selectivity ratio, which helps minimize damage to the second core layers 220 during removal of the first spacers 510 and the first pattern transfer layer 310.

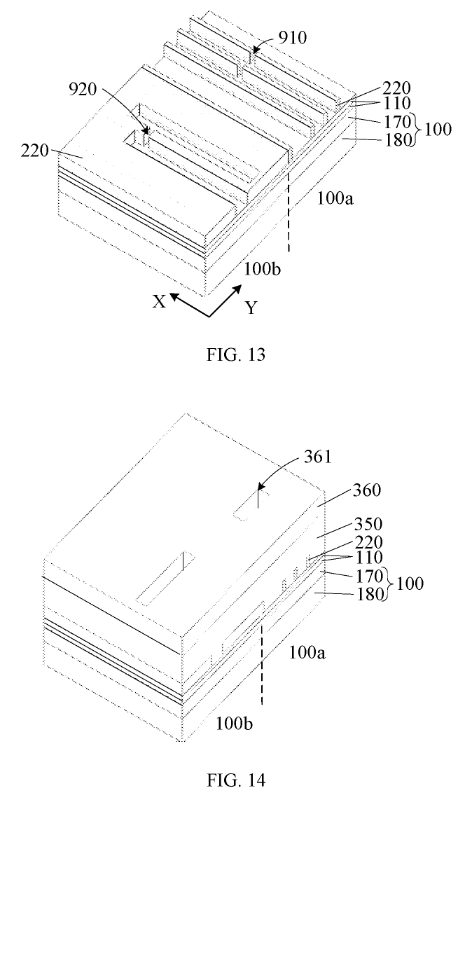

Referring to FIG. 12 and FIG. 13, after removing the first spacers 510 and the first protective layer 610 and before forming second spacers covering the sidewalls of the second core layers 220, the method further includes patterning the second core layers 220 and forming first separation openings 910 that cut off the second core layers 220 in the first area 100a along the first direction, and forming second separation openings 920 that cut off the second core layers 220 in the second area 100b along the first direction.

The first separation openings 910 are used for subsequent formation of first separation structures, and the second separation openings 920 are used for subsequent formation of second separation structures.

The first and second separation openings 910 and 920 cut off the second core layers 220 in the first area 100a and the second area 100B along the first direction, respectively. Optionally, in some embodiments, the step of patterning portions of the second core layers 220 in the first area 100a and the second area 100b and forming the first separation and second openings 910 and 920 includes, referring to FIG. 12, forming a third protective layer 350 covering the second core layers 220. A fourth mask layer 360 is formed on the third protective layer 350. The fourth mask layer 360 has fourth mask layer openings 361 extending along the second direction and crossing the second core layers 220 in the first area 100a and the second area 100b. Referring to FIG. 13, the second core layers 220 is patterned through the fourth mask layer openings 361 and the third protective layer 350. The first separation openings 910 are formed that cut off the second core layers 220 in the first area 100a along the first direction. The second separation openings 920 are formed that cut off the second core layers 220 in the second area 100b along the first direction.

In some embodiments, the third protective layer 350 is a planarization layer, and the material of the third protective layer 350 includes SOC material. SOC is formed by a spin-coating process, which has relatively low process costs. Moreover, using SOC helps improve the top surface flatness of the third protective layer 350, thereby providing a favorable interface for the formation of the fourth mask layer 360.

The fourth mask layer 360 is used to pattern the second core layers 220 through the third protective layer 350.

In some embodiments, the fourth mask layer 360 includes Si-ARC and a photoresist layer on the Si-ARC.

Continuing to refer to FIG. 13, after forming the first separation openings 910 that cut off the second core layers 220 in the first area 100a along the first direction and the second separation openings 920 that cut off the second core layers 220 in the second area 100b along the first direction, the method further includes removing the third protective layer 350 and the fourth mask layer 360.

In some embodiments, based on practical requirements, the steps shown in FIGS. 12 and 13 may be repeated to form first separation openings 910 and second separation openings 920 at target locations.

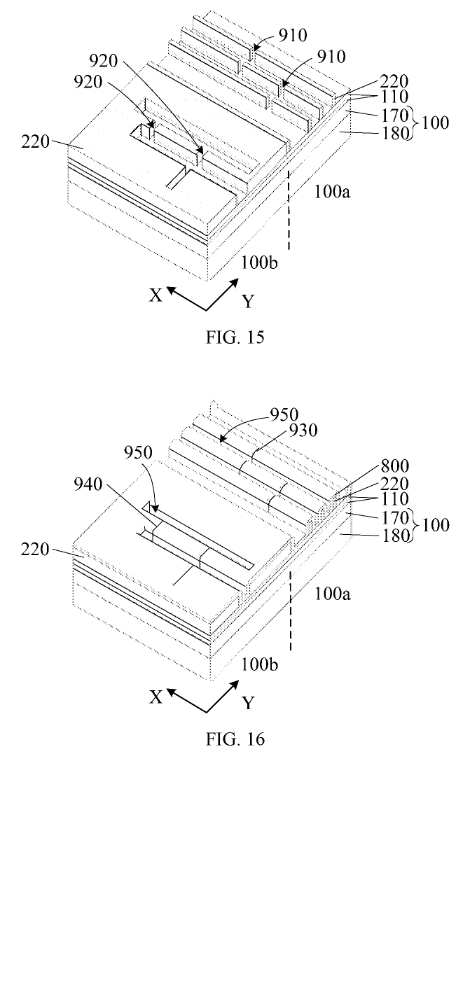

In some embodiments, the steps for forming the first separation openings 910 and the second separation openings 920 may be performed twice. As shown in FIGS. 14 and 15, the third protective layer 350 is formed to cover the second core layers 220. The fourth mask layer 360 is further formed on the third protective layer 350. Fourth mask layer openings 361 are formed in the fourth mask layer 360. The fourth mask layer openings 361 extend along the second direction, cross the second core layers 220 in the first area 100a, and cross the second core layers 220 in the second area 100b. The second core layers 220 are patterned through the fourth mask layer openings 361 and the third protective layer 350. The first separation openings 910 are formed that cut off the second core layers 220 in the first area 100a along the first direction. The second separation openings 920 are formed that cut off the second core layers 220 in the second area 100b along the first direction.

Referring to FIGS. 16 to 22, second spacers 810 are formed that cover the sidewalls of the second core layers 220.

The second spacers 810 serve as a partial etch mask for subsequent patterning of the target material layer 170 in the first area 100a and the second area 100b.

In some embodiments, the material of the second spacers 810 includes one or more of titanium oxide, titanium nitride, silicon oxide, silicon nitride, silicon oxynitride, and silicon carbide.

Titanium oxide, titanium nitride, silicon oxide, silicon nitride, silicon oxynitride, and silicon carbide may achieve a good etching selectivity ratio with the second core layers 220, thereby minimizing damage to the second spacers 810 during subsequent removal of the second core layers 220.

In some embodiments, during the step of forming the second spacers 810 covering the sidewalls of the second core layers 220, the second spacers 810 also cover the sidewalls of the first separation openings 910 and the sidewalls of the second separation openings 920. Twice the thickness of the second spacers 810 is greater than the dimension of the first separation openings 910 and the dimension of the second separation openings 920 along the first direction. As a result, the second spacers 810 on opposite sidewalls of the first separation opening 910 contact each other, forming a first separation structure 930, while the second spacers 810 on opposite sidewalls of the second separation opening 920 contact each other, forming a second separation structure 940.

The first separation structures 930 and the second separation structures 940 are used to transfer patterns to the target material layer 170, enabling direct formation of separation in the first target structures and the second target structures in the target material layer 170. After the target material layer 170 is patterned, while the first target structures and the second target structures are formed in the target material layer 170, the first target structures, which require separation, are separated, and the second target structures, which require separation, are also separated.

Optionally, referring to FIG. 16, the step of forming the second spacers 810 covering the sidewalls of the second core layers 220 includes forming a second spacer material layer 800 covering the sidewalls and tops of the second core layers 220 as well as the top of the base 100.

The second spacer material layer 800 is used to directly form the second spacers 810. Correspondingly, the material of the second spacer material layer 800 includes one or more of titanium oxide, titanium nitride, silicon oxide, silicon nitride, silicon oxynitride, and silicon carbide.

In some embodiments, an ALD process is employed to form the second spacer material layer 800 covering the sidewalls and tops of the second core layers 220 as well as the top of the base 100.

The second spacer material layer 800 formed by the ALD process exhibits excellent thickness uniformity and step coverage capability, ensuring conformal coverage of the sidewalls and tops of the second core layers 220 as well as the top of the base 100.

In some embodiments, during the step of forming the second spacer material layer 800 covering the sidewalls and tops of the second core layers 220 and the top of the base 100, the second spacer material layer 800 also fills the first separation openings 910 and the second separation openings 920.

Portions of the second spacer material layer 800 covering the sidewalls of the second core layers 220 serve as the second spacers 810. Portions of the second spacer material layer 800 filling the first separation openings 910 serve as the first separation structures 930. Portions of the second spacer material layer 800 filling the second separation openings 920 serve as the second separation structures 940.

In some embodiments, while the second spacer material layer 800 covers the sidewalls and tops of the second core layers 220 and the top of the base 100, portions of the second spacer material layer 800 on opposing sidewalls surround and form trenches 950.

The first separation structures 930 only separate first target structures corresponding to (directly below) the second core layers 220 in the first area 100a, without separating the trenches 950 surrounded by the second spacers 810 of the second core layers 220 in the first area 100a and the first target structures corresponding to the trenches 950. This is the distinctive feature of the self-aligned block (SAB) technology mentioned in the background. Similarly, the second separation structures 940 only separate the second target structures corresponding to the second core layers 220 in the second area 100b, without separating the second target structures corresponding to the trenches 950 surrounded by the second spacer material layer 800 on the sidewalls of the second core layers 220 in the second area 100b.

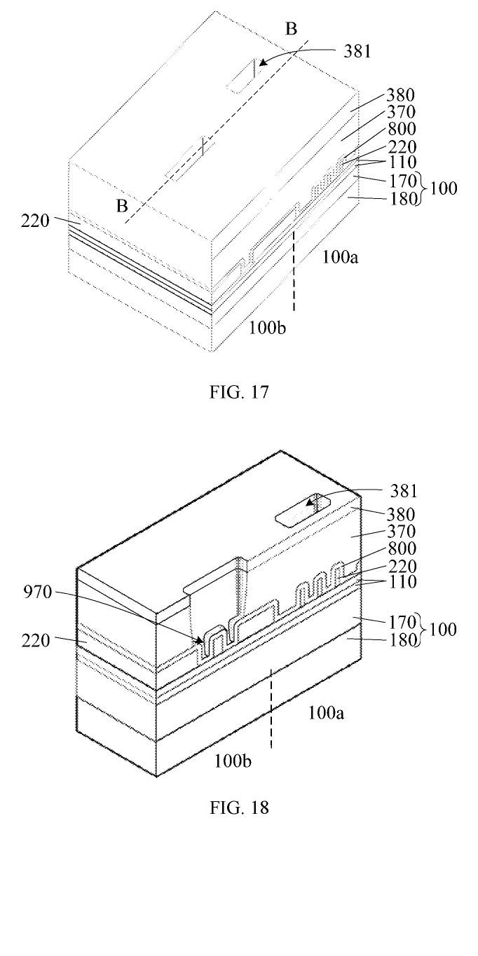

Referring to FIGS. 17 to 20, after forming the second spacer material layer 800 covering the sidewalls and tops of the second core layers 220 and the top of the base 100, and before removing the second spacer material layer 800 on the tops of the second core layers 220 and the top of the base 100, the method further includes forming third separation structures 960 extending along the second direction and in contact with the second spacers 810 in the trenches 950 of the first area 100a and the second area 100b. The third separation structures 960 separate the trenches 950 along the first direction.

The third separation structures 960 are used to transfer patterns to the target material layer 170, enabling direct formation of separation of the first target structures and separation of the second target structures corresponding to the trenches 950 in the first area 100a and the second area 100b. After the target material layer 170 is patterned and when the first target structures and the second target structures are formed in the target material layer 170, the first target structures and second target structures that require separation are separated simultaneously.

Optionally, the third separation structures 960 only separate first target structures corresponding to (directly below) the trenches 950 in the first area 100a, without separating first target structures corresponding to the second core layers 220 in the first area 100a. This is a distinctive feature of the SAB technology mentioned in the background. Similarly, in some embodiments, the third separation structures 960 only separate second target structures corresponding to the trenches 950 in the second area 100b, without separating second target structures corresponding to the second core layers 220 in the second area 100b.

Optionally, in the first area 100a, the separation transferred to the target material layer 170 by the third separation structures 960 and the separation transferred to the target material layer 170 by the first separation structures 930 are separation between adjacent first target structures. In the second area 100b, the separation transferred to the target material layer 170 by the third separation structures 960 and the separation transferred to the target material layer 170 by the second separation structures 940 are separation between adjacent second target structures. Thus, by pre-forming the first separation structures 930, the second separation structures 940, and the third separation structures 960, adjacent first target structures or adjacent second target structures may be simultaneously separated in the target material layer 170, providing a better method for forming separations with small pitches.

FIG. 18 is a cross-sectional view of FIG. 17 along a BB direction. Referring to FIGS. 17 and 18, optionally, the step of forming the third separation structures 960 extending along the second direction and in contact with the second spacers 810 in the trenches 950 of the first area 100a and the second area 100b includes forming a fourth protective layer 370 covering the second spacer material layer 800 and filling the trenches 950. A fifth mask layer 380 is formed on the fourth protective layer 370. The fifth mask layer 380 has fifth mask layer openings 381 extending along the second direction and crossing the trenches 950. Then, the fourth protective layer 370 is patterned through the fifth mask layer openings 381. The fourth protective layer 370 in positions corresponding to trenches 950 in the fifth mask layer openings 381 is removed. Third separation openings 970 are formed.

In some embodiments, the fourth protective layer 370 is a planarization layer, and the material of the fourth protective layer 370 includes SOC material. SOC is formed by a spin-coating process, which has relatively low process costs. Moreover, using SOC helps improve the top surface flatness of the fourth protective layer 370, thereby providing a favorable interface for the formation of the fifth mask layer 380.

The fifth mask layer 380 is used to pattern the fourth protective layer 370 to form the third separation openings 970.

In some embodiments, the fifth mask layer 380 includes Si-ARC and a photoresist layer on the Si-ARC.

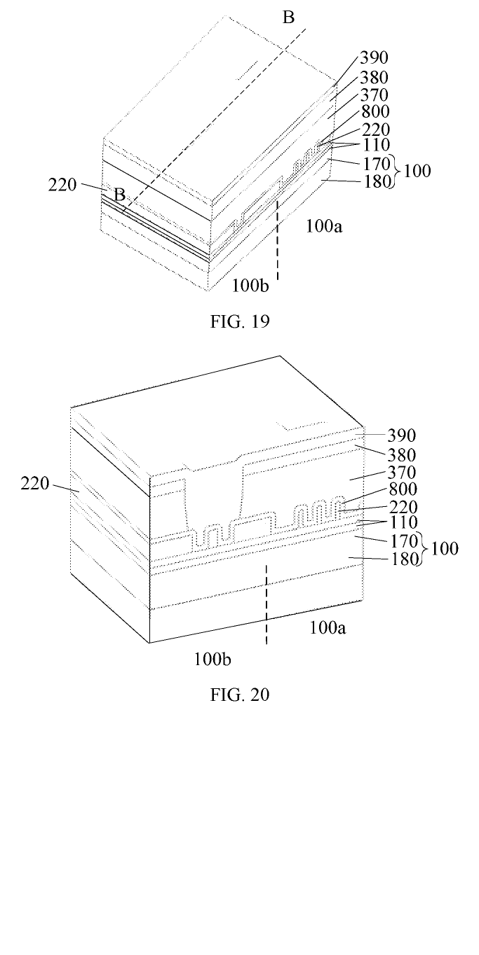

Referring to FIGS. 19 and 20, FIG. 20 is a cross-sectional view of FIG. 19 along the BB direction. A separation material layer 390 filling the third separation openings 970 is formed.

The separation material layer 390 is used to form the third separation structures 960.

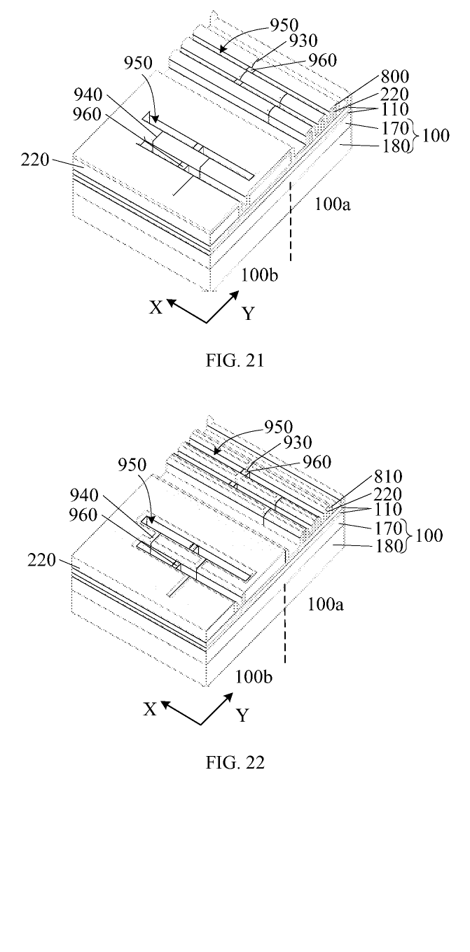

Referring to FIG. 21, after forming the separation material layer 390 that fills the third separation openings 970, the method further includes removing the fourth protective layer 370, the fifth mask layer 380, and the separation material layer 390 above the second spacer material layer 800.

Referring to FIG. 22, portions of the second spacer material layer 800 on the tops of the second core layers 220 and the top surface of the base 100 are removed, while portions of the second spacer material layer 800 on the sidewalls of the second core layers 220 are retained as the second spacers 810. Additionally, portions of the second spacer material layer 800 below the third separation material layer 390 in the trenches 950 surrounded by the second spacer material layer 800 are retained to form third separation structures 960.

In some embodiments, a dry etching process is used to remove portions of the second spacer material layer 800 on the tops of the second core layers 220 and the top surface of the base 100.

The dry etching process is anisotropic, which helps minimize damage to the second core layers 220. Furthermore, the directional nature of dry etching improves the sidewall morphology quality and dimensional accuracy of the second spacers 810.

In some embodiments, during the step of removing the second spacer material layer 800 on the tops of the second core layers 220 and the top surface of the base 100, the separation material layer 390 above the tops of the second core layers 220 is also removed. Portions of the separation material layer 390 in the third separation openings 970 are retained as the third separation structures 960 for subsequent pattern transfer to the target material layer 170.

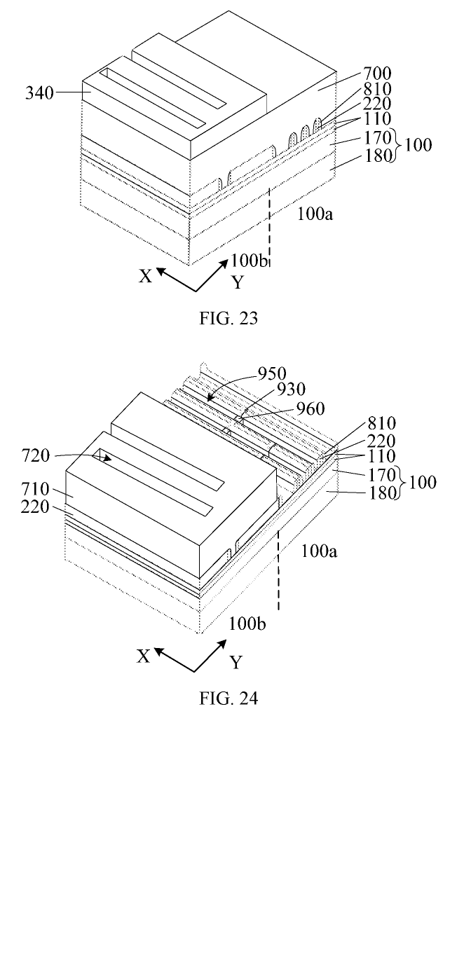

Referring to FIGS. 23 and 24, separate second protective layers 710 are formed on the second core layers 220 in the second area 100b. The second protective layers 710 have separate second protective layer openings 720 extending along the first direction and arranged parallel to each other along the second direction. The second protective layers 710 fill the second core layer openings 221. The second protective layer openings 720 expose the second core layers 220.

The second protective layers 710 serve as an etch mask for subsequent patterning of the second core layers 220 in the second area 100b.

Correspondingly, in some embodiments, during the step of forming the separate second protective layers 710 on the second core layers 220 in the second area 100b, the second protective layers 710 also fill the second core layer openings 221.

In some embodiments, during the step of forming the second protective layers 710 on the second core layers 220 in the second area 100b, the second protective layer openings 720 have a dimension of 35 nm to 200 nm along the second direction and a pitch of 76 nm to 200 nm. Accordingly, when the second core layers 220 in the second area 100b are subsequently patterned, the second core layer openings are formed with a dimension of 35 nm to 200 nm along the second direction and a pitch of 76 nm to 200 nm.

In some embodiments, the material of the second protective layer 710 includes SOC material.

Optionally, referring to FIG. 23, the step of forming the second protective layers 710 on the second core layers 220 in the second area 100b includes forming a second protective material layer 700 covering the second core layers 220 and the second spacers 810.

The second protective material layer 700 is used to form the second protective layer 710.

Correspondingly, in some embodiments, the second protective material layer 700 is a planarization layer, and the material of the second protective material layer 700 includes SOC material. SOC is formed by a spin-coating process, which has relatively low process costs. Moreover, using SOC helps improve the top surface flatness of the second protective material layer 700, thereby providing a favorable interface for the formation of the first protective layer.

In some embodiments, a third mask layer 340 is formed over the second protective material layer 700. The third mask layer 340 exposes the second protective material layer 700 in the first area 100a, and mask openings extending along the first direction are formed in the third mask layer 340 in the second area 100b.

The third mask layer 340 is used to pattern the second protective material layer 700.

In some embodiments, the third mask layer 340 includes Si-ARC and a photoresist layer on the Si-ARC.

Referring to FIG. 24, the second protective material layer 700 in the second area 100b is patterned. Portions of the second protective material layer 700 in the first area 100a are removed. Portions of the second protective material layer 700 in the second area 100b that extend partially along the first direction and partially along the second direction are removed. The remaining portions of the second protective material layer 700 located in the second area 100b are retained as the second protective layers 710.

Optionally, in some embodiments, the second protective material layer 700 is patterned using the third mask layer 340 as an etch mask.

In some embodiments, after patterning the second protective material layer 700 in the second area 100b and forming the second protective layers 710, the method further includes removing the third mask layer 340.

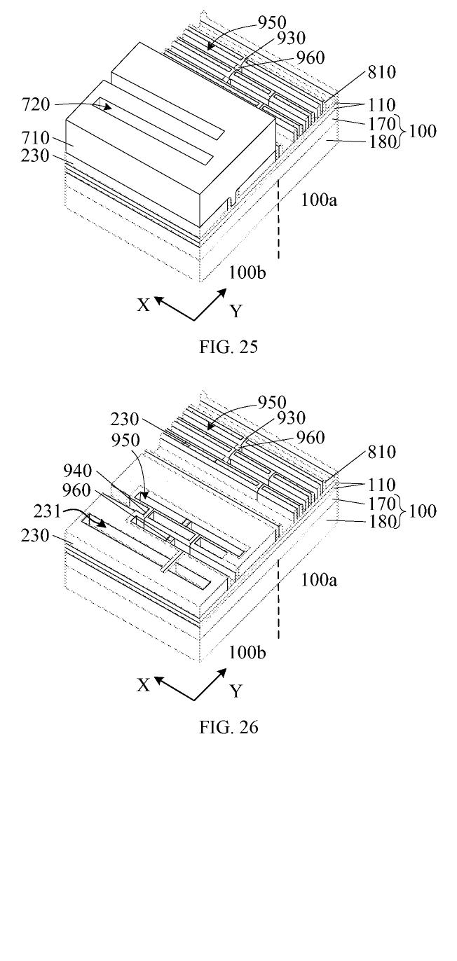

Referring to FIG. 25, the second core layers 220 are patterned using the second protective layers 710 as a mask. Portions of the second core layers 220 in the first area 100a are removed. Portions of the second core layers 220 in the second area 100b exposed by the second protective layer openings 720 are removed. Third core layer openings 231 are formed. The remaining portions of the second core layers 220 in the second area 100b are retained as third core layers 230.

The second core layers 220 are patterned using the second protective layers 710 as a mask. The second core layers 220 exposed by the second protective layer openings 720 in the second region 100b are removed. It prepares for the subsequent patterning of the target material layer 170 in the first area 100a and the second area 100b using the second spacers 810 and the third core layers 230 as a mask.

In some embodiments, a single photomask and lithography etching process are used to pattern the third mask layer 340 in the second area 100b. The third mask layer 340 is then used to pattern the second protective material layer 700. The second protective layers 710 are formed. Subsequently, the second core layers 220 are patterned using the second protective layers 710 as a mask. The third core layers 230 are formed. The process of forming the second protective layers 710 is flexible. The width and pitch of the second protective layer 710 are easy to adjust. This correspondingly makes it easy to adjust the width and pitch of the remaining second core layers 220 (i.e., the third core layers 230) in the second area 100b. It enables the formation of the second target structures with larger pitches in the second area 100b and improves design flexibility in patterning.

Correspondingly, in some embodiments, during the step of patterning the second core layers 220 using the second protective layers 710 as a mask, the third core layer openings 231 have a dimension of 35 nm to 200 nm along the second direction and a pitch of 76 nm to 200 nm.

Correspondingly, in some embodiments, during the step of patterning the second core layers 220 using the second protective layers 710 as a mask and forming the third core layers 230, the material of the third core layers 230 is the same as that of the second core layers 220. The material of the third core layers 230 includes one or more of a-Si, polycrystalline silicon, single crystal silicon, silicon oxide, advanced patterning film materials, SOC, and silicon carbide.

In some embodiments, a dry etching process is employed to pattern the second core layers 220 using the second protective layers 710 as a mask.

The dry etching process is more directional, with a higher vertical etching rate than lateral etching rate, which helps achieve better pattern transfer accuracy. This improves the dimensional precision and sidewall quality of the third core layers 230, as well as ensures the dimensional precision and sidewall quality of the second spacers 810.

Referring to FIG. 26, the second protective layers 710 are removed.

Removing the second protective layers 710 prepares for subsequent removal of the second core layers 220.

In some embodiments, an etching process is used to remove the second protective layers 710.

In some embodiments, either isotropic or anisotropic etching processes may be employed, provided that the etching selectivity ratio of the process is maintained to ensure a high selectivity between the second protective layers 710 and the third core layers 230, thereby minimizing damage to the third core layers 230 during removal of the second protective layers 710.

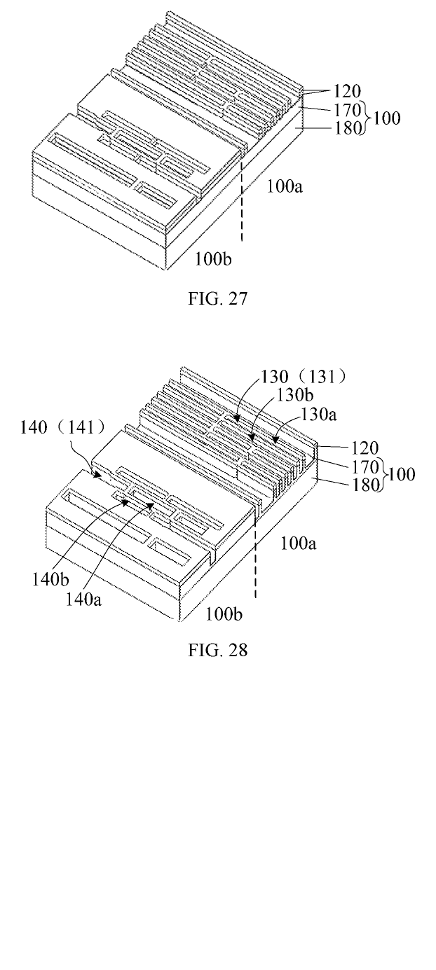

Referring to FIGS. 27 and 28, the target material layer 170 is patterned using the second spacers 810 and the third core layers 230 as a mask. First target structures 131 in the first area 100a and second target structures 141 in the second area 100b are formed.

Optionally, the target material layer 170 is patterned using the second spacers 810, the third core layers 230, the first separation structures 930, the second separation structures 940, and the third separation structures 960 as a mask. The first target structures 131 in the first area 100a and the second target structures 141 in the second area 100b are formed.

In some embodiments, the first core layers 410 are formed in the first area 100a. The first spacers 510 covering sidewalls of the first core layers 410 are formed. The first protective layer 610 is formed on the second core material layer 200 in the second area 100b. Separate first protective layer openings 620 are formed in the first protective layer 610 that extend along the first direction and are arranged parallel to each other along the second direction. The second core material layer 200 is patterned using the first spacers 810 and the first protective layer 610 as a mask to form second core layers 220. In the first area 100a, the SAQP process is used to form the second spacers 810 covering sidewalls of the second core layers 220, and pattern the target material layer 170 using the second spacers 810 as a mask. The SAQP process may form the first target structures 131 with smaller pitches. In the second area 100b, the SALELE process is used. The second protective layer 710 is formed on the second core layers 220 in the second area 100b, and the second core layers 220 are patterned using the second protective layer 710 as a mask. Subsequently, the third core layers 230 are formed, the second spacers 810 covering sidewalls of the second core layers 220 and the third core layers 230 are formed, and the target material layer 170 is patterned using the second spacers 810 and the third core layers 230 as a mask. As such, the SALELE process is implemented to form the second target structures 141 with larger pitches. That is, the SAQP and SALELE processes are effectively integrated, enabling the formation of both the first target structures 131 with smaller pitches and the second target structures 141 with larger pitches over the same base 100. This integration meets more semiconductor process requirements and improves design flexibility in patterning.

Optionally, during the step of patterning the target material layer 170 using the second spacers 810 and the third core layers 230 as a mask and forming the first target structures 131 in the first area 100a and the second target structures 141 in the second area 100b, the target material layer 170 is patterned using the first separation structures 930 and the second separation structures 940 as a mask. This results in portions of the target material layer 170 that correspond to the first separation structures 930 and separate the first target structures 131 along the first direction, and portions of the target material layer 170 that correspond to the second separation structures 940 and separate the second target structures 141 along the first direction.

In some embodiments, during the step of patterning the target material layer 170 using the second spacers 810 and the third core layers 230 as a mask, forming the first target structures 131 in the first area 100a, and forming the second target structures 141 in the second area 100b, the target material layer 170 is patterned using the third separation structures 960 as a mask. Portions of the target material layer 170 are obtained that correspond to the third separation structures 960, separate the first target structures 131 along the first direction, and separate the second target structures 141 along the first direction.

In some embodiments, during the step of patterning the target material layer 170 using the second spacers 810 and the third core layers 230 as a mask, a dielectric layer is patterned using the second spacers 810 and the third core layers 230 as a mask and first trenches 130 and second trenches 140 are formed in the dielectric layer.

The first trenches 130 provide spatial positions for subsequent formation of first metal lines, and the second trenches 140 provide spatial positions for subsequent formation of second metal lines.

Optionally, the target material layer 170 transferred from the third core layers 230 in the first area 100a may separate the first trenches 130 along the first direction, achieving design flexibility for the first trenches 130 in the first direction. Additionally, during pattern transfer to form the first trenches 130, no pattern is transferred to the target material layer 170 at positions where the first trenches 130 are not required, making the process simple and efficient.

The first trenches 130 may be divided into type-A first trenches 130a and type-B first trenches 130b arranged alternately. The type-A first trenches 130a are part of the first trenches 130 corresponding to the second core layers 220 in the first area 100a. The type-B first trenches 130b are part of the first trenches 130 corresponding to the trenches 950 surrounded by the second spacer material layer 800 on the second core layers 220 in the first area 100a.

The second trenches 140 may also be divided into type-A second trenches 140a and type-B second trenches 140b. The type-A second trenches 140a are part of the second trenches 140 corresponding to the third core layer openings 231 in the second area 100b. The type-B second trenches 140b are part of the second trenches 140 corresponding to the trenches 950 surrounded by the second spacer material layer 800 on the sidewalls of the second core layers 220 in the second area 100b.

Correspondingly, in some embodiments, a portion of the dielectric layer corresponding to the first separation structures 930 separates the type-A first trenches 130a along the first direction, a portion of the dielectric layer corresponding to the second separation structures 940 separates the type-A second trenches 140a along the first direction, and a portion of the dielectric layer corresponding to the third separation structures 960 separates the type-B first trenches 130b and type-B second trenches 140b along the first direction.

Optionally, referring to FIG. 27, the step of patterning the target material layer 170 using the second spacers 810 and the third core layers 230 as a mask includes patterning the mask material layer 110 using the second spacers 810 and the third core layers 230 as a mask and forming a second pattern transfer layer 120.

The second pattern transfer layer 120 serves as an etch mask for patterning the target material layer 170.

In some embodiments, after forming the second pattern transfer layer 120 and before patterning the target material layer 170 using the second pattern transfer layer 120 as a mask, the method further includes removing the second spacers 810 and the third core layers 230. It prepares for subsequent patterning of the target material layer 170 using the second pattern transfer layer 120 as a mask.

Referring to FIG. 28, the target material layer 170 is patterned using the second pattern transfer layer 120 as a mask.

Transferring patterns of the second spacers 810 and the third core layers 230 to the target material layer 170 through the second pattern transfer layer 120 helps improve pattern transfer accuracy, resulting in higher dimensional precision for the first target structures 131 and the second target structures 141.

Optionally, an etching process is used to pattern the target material layer 170 with the second pattern transfer layer 120 as a mask, thereby thinning the second pattern transfer layer 120 during the patterning of the target material layer 170. For example, a silicon oxide layer in the second pattern transfer layer 120 may be removed.

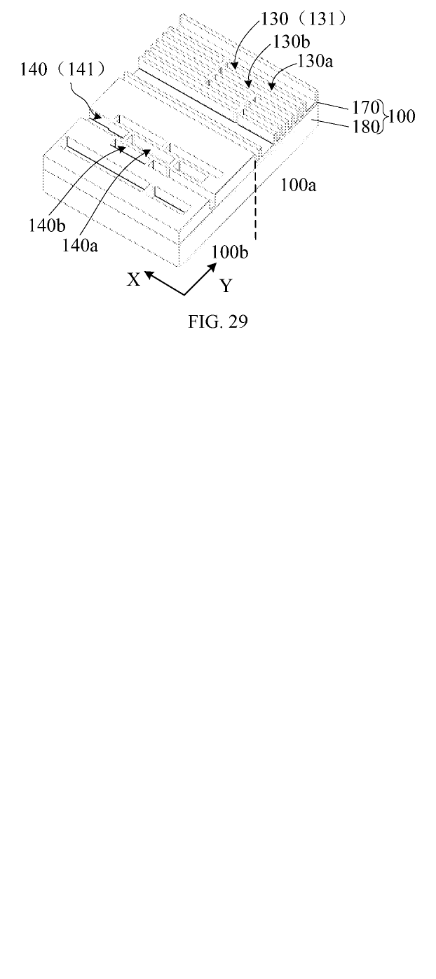

Referring to FIG. 29, after forming the first target structures 131 and the second target structures 141, the method further includes removing the second pattern transfer layer 120.

Removing the second pattern transfer layer 120 prepares for subsequent formation of first metal lines and second metal lines.

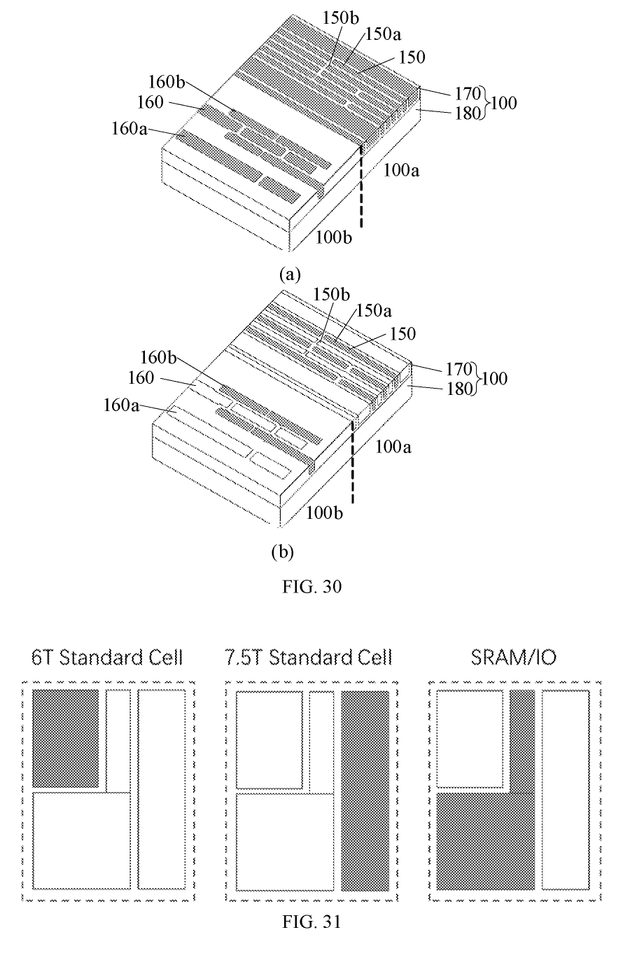

Referring to FIG. 30, after forming the first target structures 131 in the first area 100a and the second target structures 141 in the second area 100b, the method further includes forming first metal lines 150 in the first trenches 130, and forming second metal lines 160 in the second trenches 140.

The first metal lines 150 and second metal lines 160 serve as metal interconnects in back-end-of-line (BEOL) processes.

Optionally, the dielectric layer transferred from the third core layers 230 in the first area 100a may separate the first metal lines 150 in the first trenches 130 along the first direction, achieving design flexibility for the first metal lines 150 in the first direction. During pattern transfer to form the first metal lines 150, no pattern is transferred to the dielectric layer at positions where the first metal lines 150 are not required, making the process simple and efficient.

FIG. 30 illustrates the differentiation between different types of first metal lines 150 and second metal lines 160.

Optionally, the first metal lines 150 may be divided into alternately arranged type-A first metal lines 150a (shown as black-filled first metal lines 150 in the first area 100a at (b) of FIG. 30) and type-B first metal lines 150b (shown as white-filled first metal lines 150 in the first area 100a at (b) of FIG. 30). The type-A first metal lines 150a are the metal lines corresponding to the second core layers 220 in the first area 100a, while the type-B first metal lines 150b are metal lines corresponding to the trenches 950 surrounded by the second spacer material layer 800 on the second core layers 220 in the first area 100a.

Similarly, the second metal lines may be divided into type-A second metal lines 160a (shown as white-filled second metal lines 160 in the second area 100b at (b) of FIG. 30) and type-B second metal lines 160b (shown as black-filled second metal lines 160 in the second area 100b at (b) of FIG. 30). The type-A second metal lines 160a are metal lines corresponding to the third core layer openings 231 in the second area 100b. The type-B second metal lines 160b are metal lines corresponding to the trenches 950 surrounded by the second spacer material layer 800 on the sidewalls of the second core layers 220 in the second area 100b. The type-A second metal lines 160a and type-B second metal lines 160b may be alternately arranged or have adjusted pitches, widths, and lengths between them, offering greater design flexibility compared to the first metal lines 150.

Correspondingly, in some embodiments, the dielectric layer corresponding to the first separation structures 930 separates the type-A first metal lines 150a along the first direction. The dielectric layer corresponding to the second separation structures 940 separates the type-A second metal lines 160a along the first direction. The dielectric layer corresponding to the third separation structures 960 separates the type-B first metal lines 150b and type-B second metal lines 160b along the first direction.

A dielectric layer is an inter metal dielectric (IMD) layer. The dielectric layer is used to achieve electrical isolation between metal interconnect lines in a BEOL process.

Exemplarily, as shown in FIG. 31, formation methods for some embodiments are illustrated. A 6T standard cell area, a 7.5T standard cell area, and an SRAM/input-output area (SRAM/IO) are formed over the base. The black areas mark corresponding device areas.

Optionally, in the 6T standard cell area in FIG. 31, the metal pitch reaches about 30 nm, and uniform metal lines for routing and wider power rails are required. Thus, SAQP may be used in the formation process. In the 7.5T standard cell area of FIG. 31, the metal pitch is around 40 nm, and uniform metal lines for routing and wider power rails are required. Thus, SALELE may be used in the formation process. In the SRAM/IO area of FIG. 31, the metal pitch is larger than 50 nm, and there are no clear layout rules for metal routing. Thus, SALELE may be used in the formation process. Therefore, by combining SAQP and SALELE, the 6T standard cell areas, 7.5T standard cell areas, and SRAM/IO areas that have different pitch requirements may be achieved over the same base.

Although the present disclosure is illustrated as above, the present disclosure is not limited thereto. Any person skilled in the art may make various changes and modifications without departing from the spirit and scope of the present disclosure. Therefore, the protection scope of the present disclosure should be subject to the scope defined by the claims.

What is claimed is:

1. A method for forming a semiconductor structure, comprising:
providing a base, wherein the base includes a substrate and a target material layer on the base, a second core material layer and a first core material layer over the second core material layer are formed on the base, the base further includes a first area for forming a plurality of first target structures and a second area for forming a plurality of second target structures, the plurality of first target structures and the plurality of second target structures extend along a first direction, and a pitch between adjacent first target structures is smaller than or equal to a pitch between adjacent second target structures;
patterning the first core material layer and forming a plurality of first core layers being separate in the first area, extending along the first direction, and arranged parallel to each other along a second direction, wherein the first direction is perpendicular to the second direction;
forming a plurality of first spacers covering sidewalls of the plurality of first core layers;
removing the plurality of first core layers;
forming a first protective layer over the second core material layer in the second area, wherein the first protective layer has a plurality of first protective layer openings being separate, extending along the first direction, and arranged parallel to each other along the second direction;
using the first protective layer and the plurality of first spacers as a mask to pattern the second core material layer, and forming a plurality of second core layers and a plurality of second core layer openings in the plurality of second core layers corresponding to the plurality of first protective layer openings, wherein the plurality of second core layer openings are surrounded by the plurality of second core layers in the second area;
removing the first protective layer and the plurality of first spacers;
forming a plurality of second spacers covering sidewalls of the plurality of second core layers;
forming a second protective layer on the plurality of second core layers in the second area, wherein the second protective layer has a plurality of second protective layer openings being separate, extending along the first direction, and arranged parallel to each other along the second direction, the second protective layer fills the plurality of second core layer openings, and the plurality of second protective layer openings expose the plurality of second core layers;
using the second protective layer as a mask to pattern the plurality of second core layers, removing a part of the plurality of second core layers in the first area, removing a part of the plurality of second core layers exposed by the plurality of second protective layer openings in the second area, and retaining a remaining part of the plurality of second core layers in the second area as a plurality of third core layers;
removing the second protective layer; and
using the plurality of second spacers and the plurality of third core layers as a mask to pattern the target material layer, and forming the plurality of first target structures in the first area and the plurality of second target structures in the second area.

2. The method according to claim 1, wherein in a step of providing the base, the target material layer is a dielectric layer, the plurality of first target structures are a plurality of first trenches, the plurality of second target structures are a plurality of second trenches;
wherein in a step of patterning the target material layer using the plurality of second spacers and the plurality of third core layers as a mask, the dielectric layer is patterned using the plurality of second spacers and the plurality of third core layers as a mask, and the plurality of first trenches and the plurality of second trenches are formed in the dielectric layer; and
wherein after forming the plurality of first target structures in the first area and the plurality of second target structures in the second area, the method further comprises:
forming a plurality of first metal lines in the plurality of first trenches and forming a plurality of second metal lines in the plurality of second trenches.

3. The method according to claim 1, wherein in a step of providing the base, the first area includes a logic device area and the second area includes a peripheral device area.

4. The method according to claim 3, wherein a thickness of a gate oxide layer in the logic device area is smaller than a thickness of a gate oxide layer in the peripheral device area.

5. The method according to claim 1, wherein a pitch of adjacent first target structures of the plurality of first target structures is 24 nm to 38 nm, and a pitch of adjacent second target structures of the plurality of second target structures is 38 nm to 200 nm.

6. The method according to claim 1, wherein a step of patterning the first core material layer comprises forming a plurality of first mask layers being separate and over the first core material layer in the first area, the method further comprises:
patterning the first core material layer through the plurality of first mask layers, and forming the plurality of first core layers being separate in the first area; and
after forming the plurality of first mask layers, removing the plurality of first mask layers.

7. The method according to claim 1, wherein a step of forming the plurality of first spacers covering the sidewalls of the plurality of first core layers includes:
forming a first spacer material layer covering sidewalls and tops of the plurality of first core layers and a top of the second core material layer; and
removing a part of the first spacer material layer located on the tops of the plurality of first core layers and the second core material layer, and retaining a part of the first spacer material layer located on the sidewalls of the plurality of first core layers as the plurality of first spacers.

8. The method according to claim 1, wherein a step of forming the first protective layer over the second core material layer in the second area includes:
forming a first protective material layer covering the second core material layer and the plurality of first spacers; and
patterning the first protective material layer, removing a part of the first protective material layer in the first area, removing a part of the first protective material layer in the second area and partially extending along the first direction and partially extending along the second direction, and retaining a remaining part of the first protective material layer in the second area as the first protective layer.

9. The method according to claim 1, wherein in a step of forming the first protective layer over the second core material layer in the second area, the plurality of first protective layer openings have a dimension of 35 nm to 200 nm along the second direction and a pitch of 76 nm to 200 nm.

10. The method according to claim 1, wherein a dry etching process is used to pattern the second core material layer using the first protective layer and the plurality of first spacers as a mask.

11. The method according to claim 1, wherein in a step of providing the base, an etching stop layer between the first core material layer and the second core material layer is formed;
wherein before forming the first protective layer over the second core material layer in the second area, the method further includes patterning the etching stop layer using the plurality of first spacers as a mask and forming a plurality of first pattern transfer layers;
wherein in a step of using the first protective layer and the plurality of first spacers as a mask to pattern the second core material layer, the second core material layer in the first area is patterned using the plurality of first pattern transfer layers as a mask, and the plurality of second core layers being separate in the first area are formed; and
wherein after forming the plurality of second core layers, the method further includes removing the plurality of first pattern transfer layers.

12. The method according to claim 1, wherein a step of forming the plurality of second spacers covering the sidewalls of the plurality of second core layers includes:
forming a second spacer material layer covering sidewalls and tops of the plurality of second core layers and a top of the base; and
removing a part of the second spacer material layer on the tops of the plurality of second core layers and the base, and retaining a part of the second spacer material layer on the sidewalls of the plurality of second core layers as the plurality of second spacers.

13. The method according to claim 1, wherein a step of forming the second protective layer on the plurality of second core layers in the second area comprises:
forming a second protective material layer covering the plurality of second core layers and the plurality of second spacers; and
patterning the second protective material layer, removing a part of the second protective material layer in the first area, removing a part of the second protective material layer in the second area that extends partially along the first direction and partially along the second direction, and retaining a remaining part of the second protective material layer located in the second area as the second protective layer.

14. The method according to claim 1, wherein in a step of forming the second protective layer on the plurality of second core layers in the second area, the plurality of second protective layer openings have a dimension of 35 nm to 200 nm along the second direction and a pitch of 76 nm to 200 nm.

15. The method according to claim 1, wherein a dry etching process is used to pattern the plurality of second core layers using the second protective layer as a mask.

16. The method according to claim 1, wherein in a step of providing the base, a mask material layer is formed between the target material layer and the second core material layer;
wherein a step of using the plurality of second spacers and the plurality of third core layers as a mask to pattern the target material layer includes:
using the plurality of second spacers and the plurality of third core layers as a mask to pattern the mask material layer and forming a second pattern transfer layer;
wherein the second pattern transfer layer is used as a mask to pattern the target material layer; and
wherein after forming the plurality of first target structures and the plurality of second target structures, the method further includes removing the second pattern transfer layer.

17. The method according to claim 16, wherein after forming the second pattern transfer layer and before patterning the target material layer using the second pattern transfer layer as a mask, the method further includes removing the plurality of second spacers and the plurality of third core layers.

18. The method according to claim 16, wherein in a step of providing the base, a material of the first core material layer includes one or more of amorphous silicon, polycrystalline silicon, single crystal silicon, silicon oxide, advanced patterning film (APF) material, spin on carbon (SOC), and silicon carbide, and a material of the second core material layer includes one or more of amorphous silicon, polycrystalline silicon, single crystal silicon, silicon oxide, APF material, SOC, and silicon carbide.

19. The method according to claim 1, wherein after removing the first protective layer and the plurality of first spacers and before forming the plurality of second spacers covering the sidewalls of the plurality of second core layers, the method further comprises:
patterning the plurality of second core layers, forming a plurality of first separation openings that cut off the plurality of second core layers in the first area along the first direction, and forming a plurality of second separation openings that cut off the plurality of second core layers in the second area along the first direction;
wherein in a step of forming the plurality of second spacers covering the sidewalls of the plurality of second core layers, the plurality of second spacers cover sidewalls of the plurality of first separation openings and sidewalls of the plurality of second separation openings, the plurality of second spacers on opposite sidewalls of the plurality of first separation openings contact each other to form a plurality of first separation structures, and the plurality of second spacers on opposite sidewalls of the plurality of second separation openings contact each other to form a plurality of second separation structures; and
wherein in a step of using the plurality of second spacers and the plurality of third core layers as a mask to pattern the target material layer and forming the plurality of first target structures in the first area and the plurality of second target structures in the second area, the target material layer is patterned using the plurality of first separation structures and the plurality of second separation structures as a mask, a plurality of first portions of the target material layer are obtained that correspond to the plurality of first separation structures and separate the plurality of first target structures along the first direction, and a plurality of second portions of the target material layer is obtained that correspond to the plurality of second separation structures and separate the plurality of second target structures along the first direction.

20. The method according to claim 12, wherein in a step of forming the second spacer material layer covering the sidewalls and tops of the plurality of second core layers and the top of the base, the second spacer material layer on opposing sidewalls surrounds a plurality of trenches;
wherein after forming the second spacer material layer covering the sidewalls and tops of the plurality of second core layers and the top of the base, and before removing the part of the second spacer material layer on the tops of the plurality of second core layers and the base, the method further includes forming a plurality of third separation structures extending along the second direction and in contact with the plurality of second spacers in the plurality of trenches in the first area and the second area, and the plurality of third separation structures separate the plurality of trenches along the first direction, and
wherein in a step of patterning the target material layer using the plurality of second spacers and the plurality of third core layers as a mask and forming the plurality of first target structures in the first area and the plurality of second target structures in the second area, the target material layer is patterned using the plurality of third separation structures as a mask, and a plurality of portions of the target material layer are obtained that correspond to the plurality of third separation structures and separate the plurality of first target structures and the plurality of second target structures along the first direction.
